(19) United States
(12) Patent Application Publication
(10) Pub. No.: US 2025/0299919 A1
(43) Pub. Date: Sep. 25, 2025

(54) ION IMPLANT DOSE MONITORING BY THERMAL WAVE MEASUREMENT

(71) Applicant: Infineon Technologies AG, Neubiberg (DE)

(72) Inventors: Sedat Dogan, Villach (AT); Bernhard Leitl, Klagenfurt (AT); Robert Meszaros, Villach (AT)

(21) Appl. No.: 19/077,388

(22) Filed: Mar. 12, 2025

(30) Foreign Application Priority Data
Mar. 19, 2024 (DE) 102024107786.7

(51) Int. Cl. H01J 37/317; H01J 37/304

(52) U.S. Cl. CPC H01J 37/3171; H01J 37/304; H01J 2237/24535; H01J 2237/31703

(57) ABSTRACT

A method of deriving a corrected thermal wave signal for improving accuracy of monitoring lattice damage caused by ion beam implantation in a crystalline substrate includes obtaining a measured ion beam current signal indicative of the ion beam current used for ion beam implantation in the substrate. A thermal wave measurement is performed on the crystalline substrate after ion beam implantation to obtain a measured thermal wave signal. The corrected thermal wave signal is calculated based on the measured ion beam current signal and the measured thermal wave signal.

### TECHNICAL FIELD

This disclosure relates generally to the field of thermal wave measurement on a crystalline substrate, and in particular to the technique of ion implant dose monitoring by thermal wave measurement.

### BACKGROUND

Thermal wave (TW) measurements are becoming standard for monitoring of ion implantation processes. Before a TW signal can be used for implant dose monitoring it needs to be stabilized. Fluctuations of the TW signal are induced by a variety of sources such as natural decay of lattice damage over time (also referred to as lattice damage relaxation), implant-energy variations, substrate variations, etc.

Lattice damage relaxation is a phenomenon which causes a gradual decrease in the measured TW signal as a function of the time after ion implantation. Due to self-annealing of crystal defects, it can take weeks or months until the crystalline lattice is relaxed.

It is known to accelerate the lattice damage relaxation process by using laser annealing (so-called laser-forced lattice damage relaxation). However, this method of decay compensation may not be sufficient to adequately compensate for the TW signal if there are other sources of TW signal variation, such as a slight deviation in implantation process conditions. This can become a more serious problem if the TW measurements are used for dose monitoring, as any process deviations in the implantation process are difficult to control.

### SUMMARY

According to an aspect of the disclosure, a method of deriving a corrected thermal wave signal for improving accuracy of monitoring lattice damage caused by ion beam implantation in a crystalline substrate includes obtaining a measured ion beam current signal indicative of the ion beam current used for ion beam implantation in the substrate. A thermal wave measurement is performed on the crystalline substrate after ion beam implantation to obtain a measured thermal wave signal. The corrected thermal wave signal is calculated based on the measured ion beam current signal and the measured thermal wave signal.

According to another aspect of the disclosure, a first computer program product comprises one or more non-transitory computer readable media storing a computer program operable, when executed by a computer, to direct the computer to carry out the method described above.

According to another aspect of the disclosure, a device for monitoring lattice damage caused by ion beam implantation in a crystalline substrate based on a thermal wave measurement on the crystalline substrate includes a data processing unit configured to carry out the method described above.

According to another aspect of the disclosure, a method of implanting ions in a crystalline substrate includes calculating a corrected thermal wave signal according to the method described above. A corrective implantation process based on the corrected thermal wave signal is then performed.

According to another aspect of the disclosure, a second computer program product comprises one or more non-transitory computer readable media storing a computer program operable, when executed by a computer, to direct the computer to control the corrective implantation process of the method described above.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a diagram illustrating the dependency of a measured TW signal on time.

FIG. 2 is a block diagram illustrating units and signals used in a process of deriving a corrected thermal wave signal for improving accuracy of monitoring lattice damage caused by ion beam implantation in a crystalline substrate.

FIG. 3 is a diagram illustrating the correlation between a measured ion beam current and a measured TW signal obtained for an ion implantation process with fixed implant conditions.

FIG. 4A is a diagram illustrating a TW signal without ion beam current correction obtained for an ion implantation process with fixed implant conditions.

FIG. 4B is a diagram illustrating a TW signal with ion beam current correction obtained for an ion implantation process with fixed implant conditions.

FIG. 5 is a flowchart illustrating exemplary stages of a method of deriving a corrected TW signal.

FIG. 6 illustrates an example of a substrate map indicative of an implant dose distribution on the substrate as obtained by TW measurement.

FIG. 7 is a block diagram illustrating a process control unit and signals used in a process of implanting ions in a crystalline substrate by performing a corrective implantation process based on the corrected TW signal.

FIG. 8 is a flowchart illustrating exemplary stages of a method of implanting ions in a crystalline substrate by using a corrective implantation process.

### DETAILED DESCRIPTION

It is to be understood that the features of the various exemplary embodiments and examples described herein may be combined with each other unless specifically noted otherwise. Furthermore, individual processes and/or device features described for exemplary methods or devices disclosed herein may be omitted unless explicitly stated as essential process or device features.

As used in this specification, the terms “electrically connected” or “electrically coupled” or similar terms are not meant to mean that the elements are directly contacted together; intervening elements may be provided between the “electrically connected” or “electrically coupled” elements, respectively. However, in accordance with the disclosure, the above-mentioned and similar terms may, optionally, also have the specific meaning that the elements are directly contacted together, i.e. that no intervening elements are provided between the “electrically connected” or “electrically coupled” elements, respectively.

TW measurements, also referred to as TP (thermal probe) measurements, are used to measure lattice damage in crystalline substrates, e.g. in semiconductor substrates. For example, lattice damage may be induced by energetic ions directed on the crystalline substrate during an ion beam implantation process. As the lattice damage caused by the energetic ions is proportional to the ion implant dose in the semiconductor substrate, TW measurements are capable of monitoring the ion implant dose in a semiconductor substrate.

TW measurements are known in the art. For example, in a TW measurement, a modulated pump laser beam is directed on the crystalline substrate for periodically exiting the substrate. Crystal damage caused by implanted ions leads to more trapped states in the substrate lattice where carriers photo-exited by the pump laser can recombine. This leads to a decrease of carrier lifetime, which has a direct effect on the reflectivity at the surface of the substrate.

TW measurements may rely on a detection of reflected light from the substrate. By monitoring the changes in reflectivity of the substrate at the surface, information about the amount of crystal damage (and thus about the ion implant dose) can be derived.

In other words, TW measurements provide information on the actual ion implant dose caused by ion beam implantation in a crystalline substrate. TW measurements can therefore be used to control the ion beam implantation process towards more accurately reaching the target implant dose.

It is known in the art that lattice damage relaxation over time is a phenomenon which causes a gradual decrease in the measured TW signal as a function of time after ion implantation. Therefore, it is known to apply a time correction to the measured TW signal in order to compensate this effect.

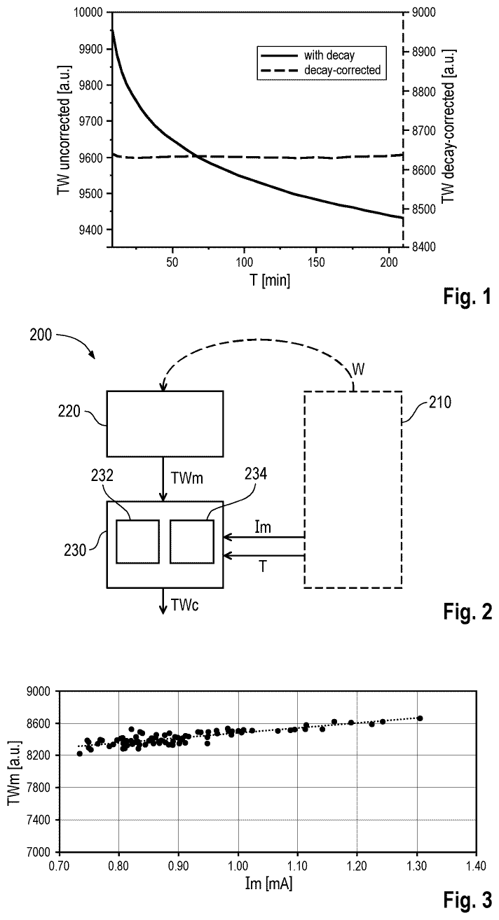

Referring to FIG. 1, on the left side of the diagram (solid line), the scale for the measured, uncorrected TW signal (in arbitrary units) is shown. The uncorrected TW signal is strongly dependent on the time period T after the implantation process ended (at T=0). The implantation conditions (implant species, implant energy, target implant dose, etc.) were fixed throughout all TW measurements.

On the right side of the diagram (dashed line), the scale for the TW decay-corrected signal is shown. The TW decay-corrected signal is the time-corrected TW signal, i.e. the TW signal stabilized against the lattice damage relaxation phenomena. The TW decay-corrected signal may correspond to the “relaxed” TW signal (corresponding to T=infinity), which can be measured after a laser-forced relaxation has been performed. The TW decay-corrected (i.e., time-corrected) signal is dependent on the implant conditions but not on time. It represents the lattice damage and thus the (actual) ion implant dose in the substrate.

The time-corrected TW signal (TW decay-corrected) can be calculated based on the measured uncorrected TW signal (scale on left side of FIG. 1), the knowledge of a decay time period (e.g., the time period T between the ion beam implantation process ended and the measurement was performed) and the decay function. In other words, if the decay function has been established, the lattice damage can be monitored based on the measured TW signal and the time period T between ion implantation and measurement.

According to the disclosure, further process variations contributing to TW signal fluctuations are taken into account. More specifically, it has been found that the ion beam current used in the implantation process is a significant contributor to TW signal fluctuations. Therefore, a measured ion beam current signal is used to compensate for TW signal fluctuations.

For example, the ion beam current may be measured before the implantation process or substrate-to-substrate during the implantation process and the TW signal may be corrected substrate-to-substrate. The correction of the measured TW signal based on the measured ion beam current improves the stability of the (e.g., substrate-to-substrate) TW signal values and thus the accuracy of monitoring lattice damage caused by ion beam implantation in the crystalline substrates.

FIG. 2 illustrates a setup 200 for considering the measured ion beam current signal Im for TW signal correction. Reference sign 210 generally relates to the ion beam implantation process and/or equipment (e.g., implanter) used for ion beam implantation.

The ion beam implantation process/equipment 210 may be characterized by implantation parameters, for example the implant species, the implant energy E and the target implant dose D. Other implantation parameters which may, e.g., be optionally considered are the implant angle (tilt) and/or the rotation (twist) of the substrate (wafer). For example, a parameter set [B/100 keV/5E+13] relates to the implant species B (boron), an implant energy E=100 keV and a target implant dose Dt=5×10¹³ cm⁻².

For a given implantation process with fixed implant conditions, all implant parameters are pre-selected and fixed. Further, a targeted ion beam current It is set. The actual ion beam current may then be set by tuning the ion beam source so that the actual ion beam current (measured ion beam current Im) corresponds to the targeted ion beam current It within a process window of, e.g., Im=It±0.1 mA. Further, depending on the design of the implanter, the measured ion beam current Im may be used to calculate the scan speed of the ion beam spot and the number of scans per substrate required to achieve the required target implant dose Dt. Tuning of the ion beam source may, e.g., be performed before starting the implantation process on the product substrates (wafers).

During the implantation process (fixed implant conditions typically for a number of substrates subjected substrate-to-substrate to this implantation process), the tuned ion beam current and the correspondingly calculated scan speed and/or number of scans may, e.g., be kept constant. That is, every implant condition may have its own targeted fixed ion beam current It with a defined process window limit. All substrates which are implanted with the same implant conditions have the same targeted ion beam current It. The actual (measured) ion beam current Im may be the measured ion beam current set during tuning of the ion beam source, or it may be measured substrate-to-substrate during the subsequent implantation process.

After ion beam implantation has been performed on a specific substrate (wafer), the substrate is subjected to TW measurement processing. TW measurement is performed by a TW measurement unit 220. To this end, the substrate may, e.g., be transferred from the ion beam implantation process and/or equipment 210 to the TW measurement unit 220 (arrow W).

For example, the TW measurement unit 220 is configured to direct a modulated pump laser beam on the crystalline substrate and receives a signal (e.g., reflected light) from the crystalline substrate (which has been subjected to the ion beam implantation process before). The TW measurement unit 220 outputs a measured TW signal TWm. The signal TWm is based on the signal received from the crystalline substrate (e.g., on the intensity of the reflected light). The TW measurement may be performed substrate-to-substrate.

The measured TW signal TWm is fed to a device for monitoring lattice damage 230. The device for monitoring lattice damage 230 may include a computing device 232. It may further include a non-transitory memory 234 on which a first computer program product can be stored.

The device for monitoring lattice damage 230 is configured to calculate a corrected TW signal TWc based on the measured TW signal TWm and on the measured ion beam current signal Im. That is, the corrected TM signal TWc is a function f of the measured TW signal TWm and the measured ion beam current signal Im.

TWc=f(TWm,Im) (equation 1)

The measured ion beam current signal Im may, e.g., be measured substrate-to-substrate. Thus, substrate-to-substrate TW signal fluctuations may be compensated. In other words, an (e.g., substrate-to-substrate) ion beam current signal compensation may be applied to improve the stability of the (e.g., substrate-to-substrate) TW measurements. In other examples, a run-to-run ion beam current signal compensation may be applied, wherein each run involves ion beam implantation performed on a plurality of substrates with the same implant conditions.

Further, as described above, a decay time compensation based, e.g., on T may be carried out in the device for monitoring lattice damage 230.

For correcting the measured TW signal against variations of the ion beam current, an ion beam current sensitivity S for the specific implantation process used needs to be known. FIG. 3 illustrates a correlation between the measured ion beam current signal Im (in mA) and the measured TW signal TWm (in arbitrary units).

The correlation may, e.g., be obtained by collecting for one specific implantation process (with specific implantation parameters, e.g., [B/100 keV/5E+13]) measured TWm values for different values of the ion beam current signal Im. This calibration may, e.g., be done in a separate calibration process by tuning the ion beam current Im and recording the TWm signal as a function of Im. Another possibility to obtain the ion beam current sensitivity S is to monitoring in parallel with the substrate-to-substrate implantation process the trend of the ion beam current Im for each measured TW signal value TWm and to derive the ion beam current sensitivity S from such history data (relating to the same implant conditions).

In general, for obtaining the sensitivity S, TWm values were collected per ion beam implantation in a plurality of substrates for one implantation process with fixed implant conditions, and the corresponding Im values were monitored. Further, in this example, the time period T between implantation and TW measurement was fixed in order to obtain more stable values.

FIG. 3 shows a correlation of ion beam current Im and TWm values. That is, the fluctuations of the TWm values show a dependency with the measured ion beam current signal Im. Approximately, a linear correlation between TWm and Im is obtained.

The reason why not a perfect linear behavior is obtained may, e.g., be due to oxide thickness variations. Since the TW measurement method which was applied here is based on reflectivity changes of the substrate due to crystal damage induced by the ions, any change in oxide thickness may impact the stability of the measured TW signal TWm as well.

An ion beam current sensitivity S may be calculated by fitting a curve to the TWm values. The sensitivity S is indicative of a change of the measured TW signal TWm from a change in the measured ion beam current signal Im at constant implant dose (fixed implantation parameters). The sensitivity S (for a specific implant process, e.g. constant implant conditions) may be written as

S=ΔTWm/ΔIm (equation 2).

The sensitivity S may be expressed as a function S(Im) which corresponds to the slope of the fitting curve of FIG. 3. In this example the sensitivity S may, e.g., be a constant (also denoted by S).

The calculation of the corrected TW signal TWc may include adding an ion beam current compensation signal TWcomp to the measured TW signal TWm:

TWC=TWcomp+TWm (equation 3).

The ion beam current compensation signal TWcomp may be calculated based on the sensitivity S and a comparison of the measured ion beam current signal Im with an ion beam current targeted value It.

TWcomp=S×F, wherein, e.g., F=Im−It (equation 4).

That is, determining the mismatch of the measured ion beam current Im to the targeted ion beam current It allows to compensate the impact of ion beam current on the TW signal according to equation 3.

It is to be noted that the change in the TWm signal due to a change in the ion beam current in FIG. 3 is not due to an implant dose change but to a change in the lattice damage. Due to the variations in the ion beam current Im, there are changes in the implant dose rate. High implant dose rates cause different damage to the crystal lattice than low implant dose rates, although the total implant dose remains the same. For example, if the ion beam current Im is doubled and the time during which the substrate is exposed to the ion beam current Im is halved (e.g., by doubling the scan speed), the implant dose remains the same, but not the lattice damage. This effect leads to the ion beam current-dependent portion of the TWm signal which is expressed by TWcomp.

As known in the art, the measured ion beam current signal Im may be obtained by a variety of techniques. For example, one or more Faraday cups may be used for measuring the ion beam current signal Im. In some examples, one measurement value per substrate may, e.g., be obtained. In other examples, the ion beam current Im is, e.g., measured between tuning of the ion beam source and the start of the implant process. This average ion beam current value may then be used as the ion beam current Im for all substrates subjected to the implantation process.

Still referring to FIG. 2, it is to be noted that a decay time compensation depending on the time period T is not necessarily required in the above process. While in FIG. 2 the decay time compensation may, e.g., be performed in the device for monitoring lattice damage 230, it is also possible to perform this compensation (correction) in the thermal wave measurement unit 220. That is, the measured TW signal TWm may, e.g., be already compensated for other sources of TW signal fluctuations than the fluctuations associated with the ion beam current Im.

Other sources of TW signal fluctuations are, e.g., oxide thickness variations on the surface of the substrate (e.g., silicon wafer) and implant energy E fluctuations. However, it has been found that the ion beam current fluctuations which are compensated in accordance with this disclosure are often the main contributor to substrate-to-substrate TWm signal fluctuations.

More specifically, one aspect of the disclosure is that there is a (linear) dependency between the measured TW signal TWm and the measured ion beam current Im. This dependency may be determined in advance as a calibration curve (sensitivity S). The calibration curve (or, e.g., straight calibration line) may be dependent on the following influencing variables:

Design of the implanter and the measuring system: Depends on how the implantation is carried out, e.g. if a ribbon beam or a scanning beam method is used, and/or how the ion beam current is measured (e.g., which design of Faraday cup arrangement is used). Normally, the implanter and the ion beam current measuring device (e.g., Faraday cup arrangement) are matched to each other. It has, however, been found that the TW fluctuations due to the implanter and the measuring system (tool noise) are not particularly large. Thus, the sensitivity S may be valid for different implanters/measuring systems.

Substrate differences: The calibration curve depends on which substrate (e.g. Si or Sic) is used and/or how thick the (optional) oxide layer over the substrate is. The thickness of the oxide layer influences the reflectivity of the surface. If there is no oxide layer, surface contamination, for example, may influence the TW signal. For example, the calibration curve (sensitivity S) may be specific to the type of substrate and/or surface condition.

Process fluctuations: The calibration curve depends on the implant energy E, the target implant dose Dt, the implant species (e.g. phosphorus or boron), and, e.g., the implant angle. These fluctuations are also not particularly large compared to the fluctuations caused by the ion beam current. Thus, the calibration curve may not consider these fluctuations, for example.

In practice, the TW signal TWm for obtaining the calibration curve (sensitivity S) may be measured on a test wafer. However, it is also possible to measure the TW signal TWm on a product wafer, i.e. on a wafer that has already been processed. This is possible because the TW measurement is non-destructive, i.e. it does not damage the wafer. The calibration curve (sensitivity S) does not have to be derived each time before an implantation process is started. Rather, a predetermined calibration curve (sensitivity S) can be assigned to each implant condition.

Before starting an ion implantation process, first, the ion beam current is set. The ion beam current is set to a targeted ion beam current It within a specific process window.

Before or during the implantation process, the actual ion beam current is measured to obtain the signal Im. If the ion beam current is measured during the implantation process, it can be measured for each substrate, for example. For example, a Faraday cup measuring arrangement is used that also works during the process.

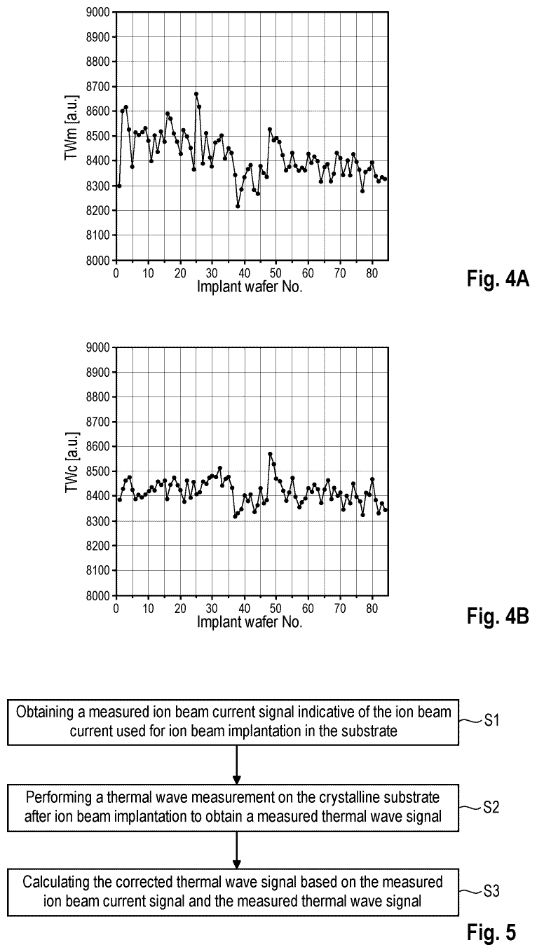

The diagram of FIG. 4A shows substrate-to-substrate TWm variations when the ion beam current fluctuations were not compensated (i.e., when the measured ion beam current signal values Im were not considered for monitoring the lattice damage in device 230). The measured TW signal values TWm versus the substrate number (Implant wafer No.) are depicted. The standard deviation σ of the distribution of measured TW signal values TWm was about σ=1.03%, with a range of minimum-to-maximum signal value variation of 430 TW signal units.

FIG. 4B illustrates the fluctuations of the corrected TW signal TWc for the same ion implant process (e.g., [B, 45 keV, 1.5 E+14]). With ion beam current compensation of the measured TW signal values TWm, an improvement of substrate-to-substrate TW repeatability to a standard deviation σ=0.56% and a range of minimum-to-maximum signal value variation of 251 TW signal units was obtained.

In general, using the TWc values instead of the TWm values, it seems that the TW repeatability from substrate-to-substrate is improved by this technique. Improvement of the substrate-to-substrate TW repeatability by ion beam current compensation allows to more accurately monitor substrate-to-substrate lattice damage (and thus, the implant dose) caused by ion beam implantation. Based on the concept of taking into account ion beam current fluctuations (e.g., substrate-to-substrate or run-to-run with the same implant conditions), the implant process window with regard to the initial setting of the ion beam current is less critical.

Attempts of narrowing the ion beam current process window resulted in considerably longer tuning times for the setting of the implant process, in particular for setting the initial ion beam current. These and other problems associated with the ion implant process may be avoided with the concept of considering the measured ion beam current signal Im for several TW signal corrections (e.g., substrate-to-substrate corrections), as described above.

Referring to FIG. 5, a measured ion beam current signal Im indicative of the ion beam current used for ion beam implantation in the substrate may be obtained at S1.

At S2 a TW measurement on the crystalline substrate, after ion beam implantation, may be performed to obtain a measured TW signal TWm. For example, the TWm signal may be based on or be indicative of the intensity of reflected light from the surface of the substrate. The TW measurement may provide a TWm signal depending on the location on the substrate, i.e. the measurement can be indicative of an implant dose distribution over the substrate.

At S3 the corrected TW signal TWc may be calculated based on the measured ion beam current signal Im and the measured TW Signal TWm. The corrected TW signal TWc is then the stabilized signal used for all subsequent processes in which information about the implant dose (distribution) in the substrate is needed.

To this end, the ion beam current compensation signal TWcomp may be calculated based on an ion beam current deviation signal F, which is derived by a comparison of the measured ion beam current signal Im and the targeted ion beam current It (see equation 4).

For example, the comparison may comprise subtracting the measured ion beam current signal Im and the targeted ion beam current It (e.g., equation 4).

The calculation of the ion beam current compensation signal TWcomp may include mathematically linking the sensitivity quantity S and the ion beam current deviation signal F (e.g., equation 4).

As mentioned above, before calculating the corrected TW signal TWc (e.g., equation 3), the sensitivity quantity S may be derived by correlating the measured TW signal TWm with the measured ion beam current signal Im. This calibration process of deriving the sensitivity quantity S can be implemented by a self-learning function. That is, an automated curve fit, corresponding to FIG. 3, may be carried out on a set of a plurality of data points (TWm versus Im), and the sensitivity function S (corresponding to the change in TWm as a function of a change in Im), or, in the approximate case of FIG. 3, the sensitivity quantity S corresponding to the slope of the linear relationship between TWm and Im, may be derived. That is, the sensitivity function S(Im) or sensitivity quantity S may, e.g., be obtained by calibration measurements prior to the performance of the implant process on the plurality of substrates.

A first computer program product may comprise comprises one or more non-transitory computer readable media storing a computer program operable, when executed by a computer, to direct the computer to carry out the method described above. The first computer program product may, e.g., be stored in a non-transitory (or non-volatile) memory, e.g. in the non-transitory memory 234. The computer may be implemented by or include the computing device 232 (see FIG. 2).

The method of deriving a corrected TW signal TWc may be used for improving the ion implantation process. For example, a corrective implantation process may be added based on the corrected TW signal TWc.

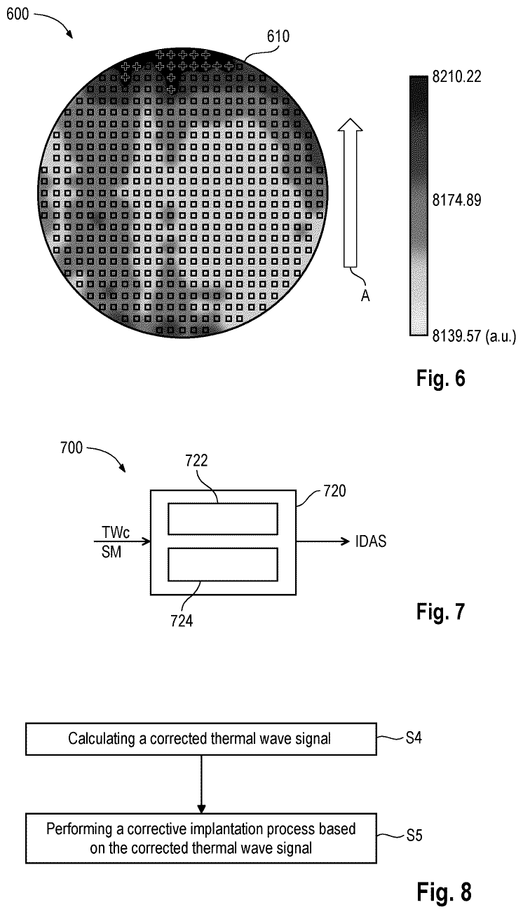

For example, a substrate map 600, as graphically shown by way of example in FIG. 6, may be generated. The substrate map (wafer map) 600 includes, e.g., the distribution of TWm data (in arbitrary TW units) over the substrate (e.g., wafer) 610 and is thus indicative of an (ion beam current-uncorrected) implant dose distribution on the substrate 610 (only a time decay correction has been applied). Arrow A indicates the scan direction of the TW measurement. As illustrated in FIG. 6, the TWmc signal (and thus, the implant dose) may vary dependent on the location on the substrate 610.

This implant dose variation, translated into a TWc data distribution over the substrate, may be used to adjust an implant dose during a subsequent corrective implantation process. The adjustment of the implant dose during the corrective implantation process may be based on the substrate map 600. That is, the higher the measured implant dose (which is proportional to TWc), the less implant dose is targeted in the corrective implantation process of the substrate.

For example, the speed of movement of the ion beam spot relative to the substrate 610 may be controlled based on the substrate map 600. For example, by adjusting (controlling) the time the implant ion beam remains at a specific location on the substrate 610, the implant dose can be accurately changed and thus “corrected” by means of the corrective implantation process. That way, the implant dose distribution (compare FIG. 6) can be made more uniform.

FIG. 7 is a block diagram 700 illustrating equipment and signals used in a process of implanting ions in a crystalline substrate 610 by performing a corrective implantation process. A process control unit 720 may include a computing device 722. It may further include a non-transitory memory 724.

The process control unit 720 receives a corrected TW signal TWc (e.g., a data signal SM based on or corresponding to the data of the substrate map 600). The process control unit 720 is programmed to control a corrective implantation process based on the corrected TW signal TWc.

Based on the corrected TW signal TWc (e.g., data signal SM), the implant dose during the corrective implantation process may be adjusted. The process control unit 720 may output an implant dose adjustment signal IDAS. The implant dose adjustment signal IDAS is configured to control the ion beam implantation process/equipment 210 in the corrective implantation process to adjust/correct the implant dose measured over the substrate 610.

For example, as described above, the implant dose adjustment signal IDAS may be used in a corrective implantation process to control the speed of movement of an ion implantation source relative to the substrate 610 when scanning over the substrate 610 (e.g., in direction A shown in FIG. 6). Other or further methods than speed control may also be used for implant dose adjustment in a corrective implantation process.

A second computer program product comprises one or more non-transitory computer readable media storing a computer program operable, when executed by a computer, to direct the computer to control the corrective implantation process as described above. The second computer program product may, e.g., be stored on a non-transitory (or non-volatile) memory, e.g. on the non-transitory memory 724 of the process control unit 720. The computer may be implemented by or comprise the computing device 722.

Referring to FIG. 8, exemplary stages of a method of implanting ions in a crystalline substrate by using a corrective implantation process in a crystalline substrate may include calculating a corrected thermal wave signal TWc according to any of the methods described above at S4.

At S5, a corrective implantation process is performed based on the corrected thermal wave signal TWc. For example, the corrective implantation process may be controlled by the implant dose adjustment signal IDAS.

For the next semiconductor component generation the requirements on the process window for the implant dose are much tighter than the current implant dose monitoring concepts can provide. The improvement of the stability of TW measurements as described herein may mean a significant improvement in implant dose monitoring and thus helps to fulfill much tighter specification limits for implant dose monitoring in future.

The following examples pertain to further aspects of the disclosure:

Example 1 is a method of deriving a corrected thermal wave signal for improving accuracy of monitoring lattice damage caused by ion beam implantation in a crystalline substrate includes obtaining a measured ion beam current signal indicative of the ion beam current used for ion beam implantation in the substrate. A thermal wave measurement is performed on the crystalline substrate after ion beam implantation to obtain a measured thermal wave signal. The corrected thermal wave signal is calculated based on the measured ion beam current signal and the measured thermal wave signal.

In Example 2, the subject matter of Example 1 can optionally include wherein calculating the corrected thermal wave signal comprises adding an ion beam current compensation signal to the measured thermal wave signal.

In Example 3, the subject matter of Example 2 can optionally include wherein the ion beam current compensation signal is based on a sensitivity quantity indicative of a change in the measured thermal wave signal as a function of a change in the measured ion beam current signal.

In Example 4, the subject matter of Example 3 can optionally include wherein the function is a linear function.

In Example 5, the subject matter of Example 3 or 4 can optionally further include before calculating the corrected thermal wave signal deriving the sensitivity quantity by correlating the measured thermal wave signal with the measured ion beam current signal.

In Example 6, the subject matter of any of Examples 2 to 5 can optionally include wherein the ion beam current compensation signal is based on an ion beam current deviation signal which is derived by a comparison of the measured ion beam current signal and a targeted ion beam current signal.

In Example 7, the subject matter of Example 6 can optionally further include wherein the comparison comprises subtracting the measured ion beam current signal and the targeted ion beam current signal.

In Example 8, the subject matter of any of Examples 3 to 5 and 6 or 7 can optionally further include wherein calculating the ion beam current compensation signal comprises mathematically linking the sensitivity quantity and the ion beam current deviation signal.

In Example 9, the subject matter of Example 8 can optionally further include wherein the mathematically linking comprises multiplying the sensitivity quantity and the ion beam current deviation signal.

In Example 10, the subject matter of any of the preceding Examples can optionally include wherein the thermal wave measurement is performed on each of a plurality of crystalline substrates to obtain a measured thermal wave signal for each crystalline substrate.

In Example 11, the subject matter of Example 10 can optionally include wherein a time interval between ion beam implantation and thermal wave measurement is fixed for the plurality of crystalline substrates.

In Example 12, the subject matter of any preceding Example can further include generating a substrate map indicative of an implant dose distribution on the substrate as calculated based on the corrected thermal wave signal.

Example 13 is a first computer program product comprising one or more non-transitory computer readable media storing a computer program operable, when executed by a computer, to direct the computer to carry out the method of any of the preceding Examples.

Example 14 is a device for monitoring lattice damage caused by ion beam implantation in a crystalline substrate based on a thermal wave measurement on the crystalline substrate, the device comprising a data processing unit configured to carry out the method of any of Examples 1 to 12.

Example 15 is a method of implanting ions in a crystalline substrate, the method comprising calculating a corrected thermal wave signal according to any of Examples 1 to 12; and performing a corrective implantation process based on the corrected thermal wave signal.

In Example 16, the subject matter of Example 15 can optionally further include generating a substrate map indicative of an implant dose distribution on the substrate as calculated based on the corrected thermal wave signal; and adjusting an implant dose during the corrective implantation process based on the substrate map.

Example 17 is a second computer program product comprising one or more non-transitory computer readable media storing a computer program operable, when executed by a computer, to direct the computer to control the corrective implantation process of the method of Examples 15 to 16.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of deriving a corrected thermal wave signal for improving accuracy of monitoring lattice damage caused by ion beam implantation in a crystalline substrate, the method comprising:
obtaining a measured ion beam current signal indicative of ion beam current used for ion beam implantation in the crystalline substrate;
after the ion beam implantation, performing a thermal wave measurement on the crystalline substrate to obtain a measured thermal wave signal; and
calculating the corrected thermal wave signal based on the measured ion beam current signal and the measured thermal wave signal.

2. The method of claim 1, wherein calculating the corrected thermal wave signal comprises:
adding an ion beam current compensation signal to the measured thermal wave signal.

3. The method of claim 2, wherein the ion beam current compensation signal is based on a sensitivity quantity indicative of a change in the measured thermal wave signal as a function of a change in the measured ion beam current signal.

4. The method of claim 3, wherein the function is a linear function.

5. The method of claim 3, further comprising:
before calculating the corrected thermal wave signal, deriving the sensitivity quantity by correlating the measured thermal wave signal with the measured ion beam current signal.

6. The method of claim 2, wherein the ion beam current compensation signal is based on an ion beam current deviation signal which is derived by a comparison of the measured ion beam current signal and a targeted ion beam current signal.

7. The method of claim 6, wherein the comparison comprises subtracting the measured ion beam current signal and the targeted ion beam current signal.

8. The method of claim 2, wherein the ion beam current compensation signal is based on a sensitivity quantity indicative of a change in the measured thermal wave signal as a function of a change in the measured ion beam current signal and further based on an ion beam current deviation signal which is derived by a comparison of the measured ion beam current signal and a targeted ion beam current signal, and wherein calculating the ion beam current compensation signal comprises mathematically linking the sensitivity quantity and the ion beam current deviation signal.

9. The method of claim 8, wherein the mathematically linking comprises multiplying the sensitivity quantity and the ion beam current deviation signal.

10. The method of claim 1, wherein the thermal wave measurement is performed on each of a plurality of crystalline substrates to obtain a measured thermal wave signal for each crystalline substrate.

11. The method of claim 10, wherein a time interval between ion beam implantation and thermal wave measurement is fixed for the plurality of crystalline substrates.

12. The method of claim 1, further comprising:
generating a substrate map indicative of an implant dose distribution on the substrate as calculated based on the corrected thermal wave signal.

13. A computer program product comprising one or more non-transitory computer readable media storing a computer program operable, when executed by a computer, to direct the computer to execute a method of deriving a corrected thermal wave signal for improving accuracy of monitoring lattice damage caused by ion beam implantation in a crystalline substrate, the computer program comprising:
program instructions to obtain a measured ion beam current signal indicative of ion beam current used for ion beam implantation in the crystalline substrate;
program instructions to, after the ion beam implantation, perform a thermal wave measurement on the crystalline substrate to obtain a measured thermal wave signal; and
program instructions to calculate the corrected thermal wave signal based on the measured ion beam current signal and the measured thermal wave signal.

14. A device for monitoring lattice damage caused by ion beam implantation in a crystalline substrate based on a thermal wave measurement on the crystalline substrate, the device comprising:
a data processing unit configured to:
obtain a measured ion beam current signal indicative of ion beam current used for ion beam implantation in the crystalline substrate;
after the ion beam implantation, perform a thermal wave measurement on the crystalline substrate to obtain a measured thermal wave signal; and
calculate the corrected thermal wave signal based on the measured ion beam current signal and the measured thermal wave signal.

15. A method of implanting ions in a crystalline substrate, the method comprising:
obtaining a measured ion beam current signal indicative of ion beam current used for ion beam implantation in the crystalline substrate;
after ion beam implantation in the crystalline substrate, performing a thermal wave measurement on the crystalline substrate to obtain a measured thermal wave signal;
calculating a corrected thermal wave signal based on the measured ion beam current signal and the measured thermal wave signal; and
performing a corrective implantation process based on the corrected thermal wave signal.

16. The method of claim 15, further comprising:
generating a substrate map indicative of an implant dose distribution on the crystalline substrate as calculated based on the corrected thermal wave signal; and
adjusting an implant dose during the corrective implantation process based on the substrate map.

17. A computer program product comprising one or more non-transitory computer readable media storing a computer program operable, when executed by a computer, to direct the computer to execute a method of implanting ions in a crystalline substrate, the computer program comprising:
program instructions to obtain a measured ion beam current signal indicative of ion beam current used for ion beam implantation in the crystalline substrate;
program instructions to, after ion beam implantation in the crystalline substrate, perform a thermal wave measurement on the crystalline substrate to obtain a measured thermal wave signal;
program instructions to calculate a corrected thermal wave signal based on the measured ion beam current signal and the measured thermal wave signal; and
program instructions to perform a corrective implantation process based on the corrected thermal wave signal.
